(19) United States
(12) Patent Application Publication
(10) Pub. No.: US 2008/0235542 A1
(43) Pub. Date: Sep. 25, 2008

(54) Electronic testing device for memory devices and related methods

(76) Inventor: Duncan Gurley, (US)

Correspondence Address: Gregory W. Osterloth;Holland & Hart, LLP, P.O. Box 8749, Denver, CO, 80201, US

(21) Appl. No.: 11/726,540

(22) Filed: Mar. 22, 2007

(51) Int. Cl. G01R 31/28

(52) U.S. Cl. 714/724

(57) ABSTRACT

Described are an electronic testing device for memory devices and related methods. The testing device, comprises a memory controller managing a transfer of data and a controller buffer disposed within the memory controller. The controller buffer transfers data between the memory controller and a memory module. The memory controller tests the memory module. The testing device is operable to test the memory module independent of an operating rate of the memory module. The memory controller receives operating data of the memory module.

### BACKGROUND

Newly manufactured electronic devices are tested to create stimulus signals and capture responses. These measurements may be used to, for example, measure actual performance against expected performance. The proper operation of the electronic devices may then be proven or faults in the devices may be traced and repaired. In particular, memory modules including a plurality of memory devices are tested to ensure capabilities prior to introduction into markets. Incorporated electronic devices may also be tested using, for example, diagnostic tests. The measurements from these tests may be used to, for example, compare actual performance against standard performance.

With advancements in memory device technology, the speeds in which the memory devices operate are increasing. For example, DDR3 (double data rate), DDR4, XDR (extreme data rate), XDR2, and newly buffered NAND/NOR (not and/nor) devices have increased operating speeds from prior memory devices. Testing, repair, and programming of faster memory devices require difficult and expensive hardware investments to conventional testing devices when data rates increase above 400 Mhz. For example, additional testing hardware is required for these high rate devices. The increased costs for testing of faster memory devices at increasing Gbit device sizes with longer test times is not apt for COT (continuity testing). One consideration for these increased costs is the requirement of massive fanouts regarding the measurement of the ability of a logic gate. Furthermore, the return path for repair solutions is not systematic for the testing equipment.

### SUMMARY OF THE INVENTION

The present invention relates to an electronic testing device for memory devices and related methods. The testing device, comprises a memory controller managing a transfer of data and a controller buffer disposed within the memory controller. The controller buffer transfers data between the memory controller and a memory module. The memory controller tests the memory module. The testing device is operable to test the memory module independent of an operating rate of the memory module. The memory controller receives operating data of the memory module.

### DESCRIPTION OF THE DRAWINGS

FIG. 1 shows an exemplary embodiment of a system according to the present invention.

FIG. 2a shows an exemplary embodiment of a first memory module that is tested using the system of FIG. 1.

FIG. 2b shows an exemplary embodiment of a second memory module that is tested using the system of FIG. 1.

FIG. 3 shows an exemplary embodiment of a method according to the present invention.

### DETAILED DESCRIPTION

The present invention may be further understood with reference to the following description and the appended drawings, wherein like elements are referred to with the same reference numerals. The exemplary embodiments of the present invention describe a system and method for performing a test on an electronic device such as a memory device. The exemplary embodiments of the present invention will be described with reference to the test being conducted for a memory module using a testing device that includes an advanced memory buffer (AMB) as a logical layer. It should be noted that those skilled in the art will understand that the present invention may be utilized to test any electronic device with increased operating rates where utilizing conventional testing equipment requires a difficult and expensive hardware investment. Those skilled in the art will understand that while the exemplary embodiments describe the testing of memory devices, other types of components may also be testing using the present invention.

Conventional testing devices may provide operating data of memory modules. However, with increased operating rates, the conventional testing devices require a difficult and expensive hardware investment to allow the testing device to keep up with the increases in operating rates. The exemplary embodiments of the present invention provides for inexpensive improvements to the testing device to provide operating data at the increased operating rates of the tested memory modules.

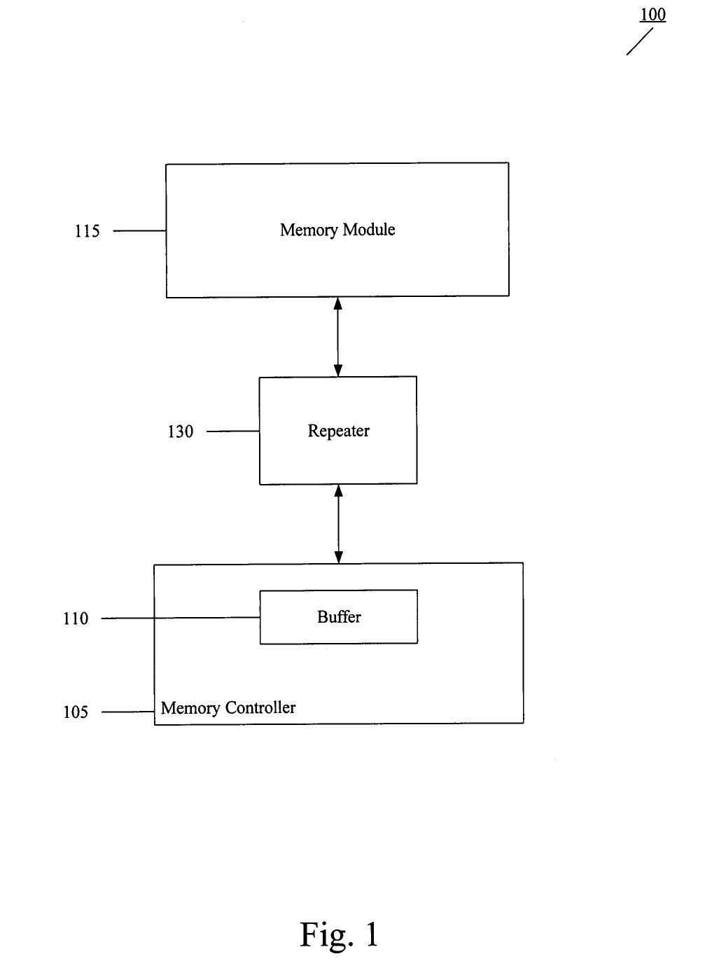

FIG. 1 shows an exemplary embodiment of a system 100 for performing an electronic test of memory devices according to the present invention. The system 100 may include a memory controller (MC) 105 that is electrically connected to a device under test (DUT) such as the memory module (MM) 115. The electrical connection may be enhanced using a repeater 130. Those skilled in the art will understand that the repeater 130 receives weak or low-level signals and retransmits these signals at a higher level or power in order to cover longer distances. Thus, if the signals to be transmitted between the memory controller 105 and the MM 115 are sufficiently strong (e.g., MC 105 and DUT 115 are in close proximity), the repeater 130 may be absent.

The system 100 may further include a bus (not shown). The bus may be electrically connected to the MC 105 and the MM 115. The bus may be a subsystem that transfers data and/or power between components such as the MC 105 and the MM 115. The bus may further assist in the testing capabilities of the MC 105. Utilizing a bus, the repeater 130 may be unnecessary as data transfers such as the signals transmitted/received from the MC 105 may be accomplished via the bus. It should be noted that the MC 105 may be further connected to, for example, a data collecting device (not shown) such as a computer, a motherboard, etc. The bus may also be connected to the data collecting device to aid in the transfer of data and/or power.

The MC 105 manages the flow of data going to and from the MM 115. The MC 105 contains the logic necessary to read and write dynamic random access memories (DRAM). The MC 105 further refreshes the DRAM by sending current through the entire memory device. Without constant refreshing performed by the MC 105, the DRAM loses the data contained therein as the capacitors of the DRAM leak current within a number of milliseconds. For example, according to the Joint Electron Device Engineering Council (JEDEC) standard, the capacitor of the DRAM leaks current in 64 milliseconds. The DRAM of the MM 115 will be discussed in detail below. The MC 105 may be, for example, a double data rate (DDR) memory controller, a dual-channel memory controller, or a fully buffered memory controller. It should be noted that the use of the DRAM is only exemplary and the memory devices may also be, for example, synchronous dynamic random access memory (SDRAM), flash drives, etc.

The MC 105 includes a buffer 110. The buffer 110 may be an AMB. Those skilled in the art will understand that the AMB may be substantially similar to an AMB that is found incorporated within a MM, such as a fully buffered dual in-line memory module (FB-DIMM). Thus, the AMB 110 of the MC 105 may be a mass produced, commercially available AMB. According to the exemplary embodiments of the present invention, the AMB may be disposed between the MC 105 and the MM 115. Therefore, the MC 105 writing to the DRAMs of the MM 115 may be performed via the buffer 110. The writing to the DRAMs of the MM 115 may be done substantially similar to the conventional writing methods where the MM 115 also includes the AMB. In an embodiment where the MM 115 also includes the AMB, the writing may entail a further step where the MC 105 writes to the DRAMs of the MM 115 first via the buffer 110 and then via the AMB of the MM 115.

Unlike the parallel bus architecture of traditional DRAMs, FB-DIMM has a serial interface between the memory controller and the AMB. The MC 105 incorporating the AMB may also exhibit the feature inherent with the FB-DIMM. The serial interface enables an increase to the width of the memory without increasing the pin count of the MC 105 beyond a feasible level. With this architecture as discussed above, the MC 105 does not write to the memory module directly but writes via the AMB. The AMB may thus compensate for signal deterioration by buffering and resending the signal. In addition, the AMB may also offer error correction, without posing any overhead on the processor or the MC 105. The AMB may also use the Bit Lane Failover Correction feature to identify bad data paths and remove them from operation, thereby dramatically reducing command/address errors. Also, since reads and writes are buffered, they may be done in parallel by the MC 105. This allows simpler interconnects, more memory bandwidth, hardware-agnostic memory controller chips (such as DDR2 and DDR3) which can be used interchangeably, etc.

The buffer 110 such as the AMB are cost efficient and are easily incorporated into the MC 105. Therefore, testing high operating rate MMs 115 may be done without the difficult and expensive hardware investment conventionally required. The buffer 110 incorporated in the MC 105 may serve as test site processors used in place of standard automatic pattern generators (APGs). Using, for example, a JEDEC DDR interface for the MC 105, any MM 115 that also exhibits the JEDEC standard may be tested using the MC 105. Those skilled in the art will understand that most MM 115 adhere to the JEDEC standard, particularly when the MM 115 further includes the AMB. Thus, the MC 105 may include a universal interface. As discussed above, because the architecture of DRAMs are substantially similar to flash drives, flash drives may also be tested using the JEDEC DDR interface of the MC 105.

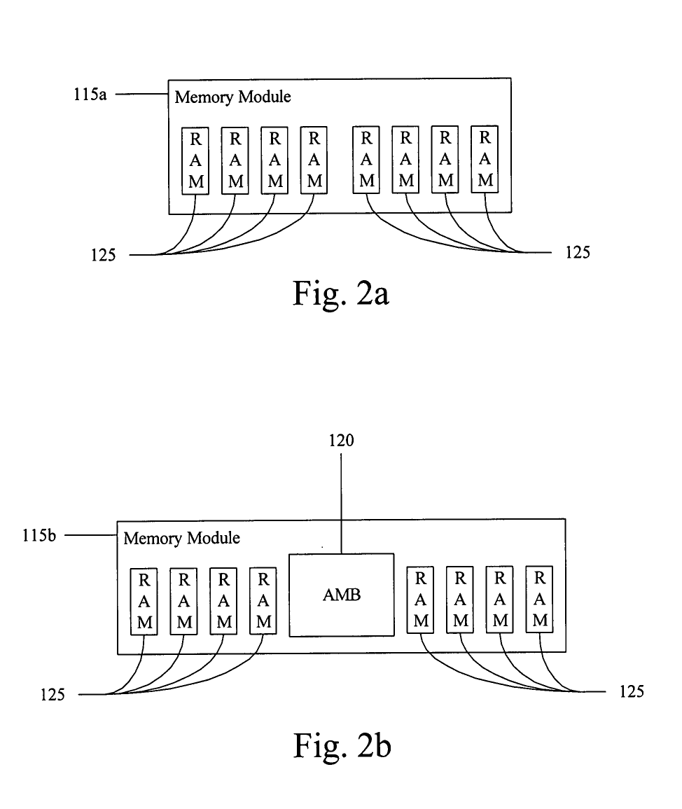

Using the MC 105 with the buffer 110 (e.g., AMB), the MC 105 may be used to test any MM 115 (e.g., MM with AMB, MM without AMB) without any further hardware requirements. As shown in FIGS. 2a-b, the MM 115 may or may not include the buffer 110. FIG. 2a shows a MM 115a that includes a plurality of random access memories (RAM) 125. The MM 115a may be a dual in-line memory module (DIMM). Those skilled in the art will understand that DIMMs have a 64-bit data path that perform more efficient data transfers. DIMMs with increased data rates may include, for example, DDR synchronous dynamic RAM (SDRAM) which is a 184-pin DIMM, DDR2 which is a 240-pin DIMM, etc. Depending on the type of DIMM, the number of RAMs, the types of RAMs (e.g., number of pins), etc. may vary. It should be noted that the use of the DIMM is only exemplary and the present invention may be applied to any memory device/module and any variation thereof.

FIG. 2b shows a MM 115b that includes a plurality of random access memories (RAM) 125 and further includes the buffer 120 (e.g., AMB). With the inclusion of the buffer 120 such as the AMB, the MM 115b may be a FB-DIMM. When the AMB is incorporated in the MM, the AMB may be disposed between the buffer 110 and the MM 115b. Thus, as discussed above, the writing to the MM 115b may be done by the MC 105 via the buffer 110 and the buffer 120. It should be noted that the use of the FB-DIMM is only exemplary and the present invention may be applied to any memory device/module including a buffer and any variation thereof.

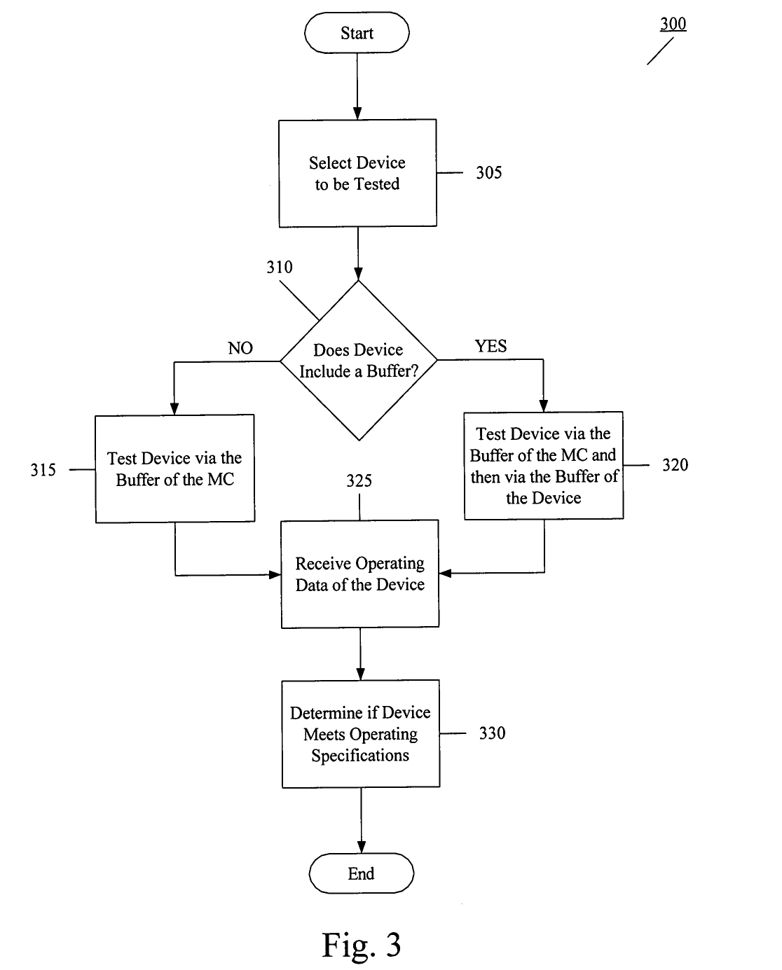

FIG. 3 shows an exemplary embodiment of a method 300 according to the present invention. The method 300 will be described with reference to the system 100 of FIG. 1 and the MMs 115a-b of FIGS. 2a-b. As will be discussed below, the method 300 may be utilized to test a DUT (e.g., MM 115) using a single testing device (e.g., MC 105) that requires no further hardware regardless of the operating speed of the DUT.

The method 300 begins at step 305 when a DUT is selected. The DUT may be, for example, the MM 115. Furthermore, the MM 115 may be either MM 115a which only includes DRAMs or MM 115b which includes DRAMs and a buffer such as the AMB. At step 310, a determination is made whether the DUT includes the buffer. That is, step 310 determines whether the DUT is MM 115a or MM 115b.

If the step 310 determines that a buffer is not present, the method continues to step 315 where the DUT is tested via the buffer 110 of the MC 105. For example, the MC 105 writes to the DRAMs of the MM 115a indirectly through the buffer 110. Upon writing to the MM 115a, reading and/or writing data may be ascertained to determine operating data of the DUT. If the step 310 determines that a buffer is present, the method continues to step 320 where the DUT is tested via the buffer 110 of the MC 105 and the buffer 120 of the MM 115b. For example, the MC 105 writes to the DRAMs of the MM 115b indirectly through both the buffer 110 and the buffer 120. Upon writing to the MM 115b, reading and/or writing data may be ascertained to determine operating data of the DUT. Upon testing in either step 315 or 320, the MC 105 receives the operating data of the MM in step 325. Upon receiving the operating data of the MM, in step 330, a determination is made if the MM meets operating specifications.

AMB logic devices offer faster SDRAM speeds and wide read/write buses at the most current speeds. As discussed above, the AMB is cost efficient and easily incorporated into the MC 105. An additional feature of the AMB is the elimination of non-recurring expenditures that are conventionally necessary. Conventional testing devices require further hardware to test high operating rate memory devices. With varying high operating rates, the further hardware is specifically altered with each device to be tested. That is, the conventional testing devices with further hardware are not scaling to the different operating rates. However, the AMB incorporated in the MC 105 allows the single testing device to perform the tests independent of the operating rate of the memory device.

As discussed above, the MC 105 may utilize the JEDEC DDR interface. The JEDEC standard further allows for an AMB memory built in self test (MBIST) or an AMB logic built in self test (lBIST). Furthermore, the AMB incorporated in the MC 105 utilizing the JEDEC standard allows for AMB MBIST functions to be improved with reprogrammable APG architectures. With the increased operating rates of the memory devices, various APG architectures may be used to measure the different combinatorial and sequential circuits. For example, with the AMB, the MC 105 may perform a D-Algorithm APG, Path Oriented Decision Making APG, Fan-Out Oriented APG, etc.

The AMB may be further used to allow the system 100 to be composed of switched AMB point to point (P2P) buses for fast error readback. The P2P architecture may also allow for a more cost efficient serial peripheral interface (SPI) for highest fanout at lower cost.

It will be apparent to those skilled in the art that various modifications may be made in the present invention, without departing from the spirit or scope of the invention. Thus, it is intended that the present invention cover the modifications and variations of this invention provided they come within the scope of the appended claims and their equivalents.

What is claimed is:

1. A testing device, comprising:
a memory controller managing a transfer of data; and
a controller buffer disposed within the memory controller, the controller buffer transferring data between the memory controller and a memory module,
wherein the memory controller tests the memory module, the testing device operable to test the memory module independent of an operating rate of the memory module, the memory controller receiving operating data of the memory module.

2. The testing device of claim 1, wherein the controller buffer is an advanced memory buffer.

3. The testing device of claim 1, wherein an interface of the memory controller is based on a Joint Electron Device Engineering Council standard.

4. The testing device of claim 1 being operable to test the memory module having a plurality of dynamic access memories.

5. The testing device of claim 1 being operable to test the memory module having a memory buffer.

6. The testing device of claim 5, wherein the memory buffer is an advanced memory buffer.

7. The testing device of claim 5, wherein the memory module is a fully-buffered dual in-line memory module.

8. The testing device of claim 5, wherein the memory controller writes to the memory module through the controller buffer and the memory buffer.

9. The testing device of claim 1, further comprising:
a repeater disposed between the memory controller and the memory module to amplify signals carrying the data.

10. The testing device of claim 1, wherein the memory module exceeds an operating rate of 400 MHz.

11. A method, comprising:
generating, by a memory controller, a set of test data for a memory module;
transferring, by a controller buffer disposed on the memory controller, the set of data to the memory module, wherein the controller buffer operates independent of an operating rate of the memory module; and
receiving operating data of the memory module in response to the set of test data.

12. The method of claim 11, wherein the controller buffer is an advanced memory buffer.

13. The method of claim 11, wherein the transferring is via a Joint Electron Device Engineering Council standard.

14. The method of claim 11, wherein the memory module includes a plurality of dynamic access memories.

15. The method of claim 11, wherein the memory module includes a memory buffer.

16. The method of claim 15, wherein the memory buffer is an advanced memory buffer.

17. The method of claim 15, wherein the memory module is a fully-buffered dual in-line memory module.

18. The method of claim 11, further comprising:
amplifying signals through a repeater disposed between the memory controller and the memory module.

19. The method of claim 11, wherein the memory module exceeds an operating rate of 400 MHz.

20. A testing device, comprising:
a memory controller managing a transfer of data; and
a buffering means transferring data between the memory controller and a memory module, the buffering means disposed within the memory controller,
wherein the memory controller tests the memory module, the testing device operable to test the memory module independent of an operating rate of the memory module, the memory controller receiving operating data of the memory module.
